(19) United States
(12) Patent Application Publication
(10) Pub. No.: US 2026/0371663 A1
(43) Pub. Date: Nov. 19, 2026

(54) VERTICAL SEMICONDUCTOR DEVICE HAVING A RESURF REGION CONNECTING A GUARD RING REGION AND A BASE REGION

(71) Applicants: Kabushiki Kaisha Toshiba, Kawasaki-shi (JP); Toshiba Electronic Devices & Storage Corporation, Kawasaki-shi (JP)

(72) Inventors: Shunsuke ASABA, Himeji Hyogo (JP); Hiroshi KONO, Himeji Hyogo (JP)

(21) Appl. No.: 19/711,857

(22) Filed: Jun. 17, 2026

Related U.S. Application Data
(62) Division of application No. 17/889,971, filed on Aug. 17, 2022, now abandoned.

(30) Foreign Application Priority Data
Mar. 22, 2022 (JP) 2022-045873

(51) Int. Cl. H10D 62/10; H10D 30/66; H10D 62/832

(52) U.S. Cl. CPC H10D 62/106; H10D 30/665; H10D 62/111; H10D 62/8325

(57) ABSTRACT

A semiconductor device includes a first semiconductor layer of a first conductivity type, second to fifth semiconductor layers of a second conductivity type, and first and second electrodes. The first semiconductor layer is provided between the first and second electrodes, and includes a termination region. The second semiconductor layer is provided between the first semiconductor layer and the second electrode, and has a first thickness in a first direction from the first electrode toward the second electrode. The third to fifth semiconductor layers are provided in the termination region. The third semiconductor layer surrounds the second semiconductor layer, and has a second thickness in the first direction. The fourth semiconductor layer surrounds the third semiconductor layer, and has a third thickness in the first direction. The second thickness is greater than the first and third thicknesses. The fifth semiconductor layer is connected to the second to fourth semiconductor layers.

### CROSS REFERENCE TO RELATED APPLICATIONS

This application is a division of U.S. Patent Application No. 17/889,971, filed on Aug. 17, 2022, which is based upon and claims the benefit of priority from Japanese Patent Application No. 2022-045873, filed on Mar. 22, 2022; the entire contents of which are incorporated herein by reference.

### FIELD

Embodiments relate to a semiconductor device.

### BACKGROUND

Improving a breakdown voltage in a termination region that surrounds an active region is important for increasing a breakdown voltage of a semiconductor device.

### BRIEF DESCRIPTION OF THE DRAWINGS

FIG. 1 is a schematic cross-sectional view showing a semiconductor device according to an embodiment;

FIG. 2 is a schematic plan view showing the semiconductor device according to the embodiment;

FIGS. 3A to 3C are schematic cross-sectional views showing a manufacturing process of the semiconductor device according to the embodiment;

FIGS. 4A and 4B are schematic cross-sectional views showing semiconductor devices according to variations of the embodiment; and

FIGS. 5A and 5B are schematic cross-sectional views showing semiconductor devices according to other variations of the embodiment.

### DETAILED DESCRIPTION

According to one embodiment, a semiconductor device includes first to fifth semiconductor layers, a first electrode and a second electrode. The first semiconductor layer of a first conductivity type includes an active region and a termination region. The termination region surrounds the active region. The first electrode is electrically connected to the first semiconductor layer. The second electrode is electrically connected to the first semiconductor layer. The first semiconductor layer is provided between the first electrode and the second electrode. The second electrode is provided on the active region. The second semiconductor layer of a second conductivity type is provided between the first semiconductor layer and the second electrode. The second semiconductor layer has a first layer thickness in a first direction directed from the first electrode toward the second electrode. The third semiconductor layer of the second conductivity type is provided in the termination region. The third semiconductor layer surrounds the second semiconductor layer, and has a second layer thickness in the first direction greater than the first layer thickness. The fourth semiconductor layer of the second conductivity type is provided in the termination region and surrounds the second semiconductor layer and the third semiconductor layer. The fourth semiconductor layer is apart from the third semiconductor layer and has a third layer thickness in the first direction less than the second layer thickness. The fifth semiconductor layer of the second conductivity type is connected to the second semiconductor layer, the third semiconductor layer and the fourth semiconductor layer. The third and fourth semiconductor layers are provided between the first semiconductor layer and the fifth semiconductor layer.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

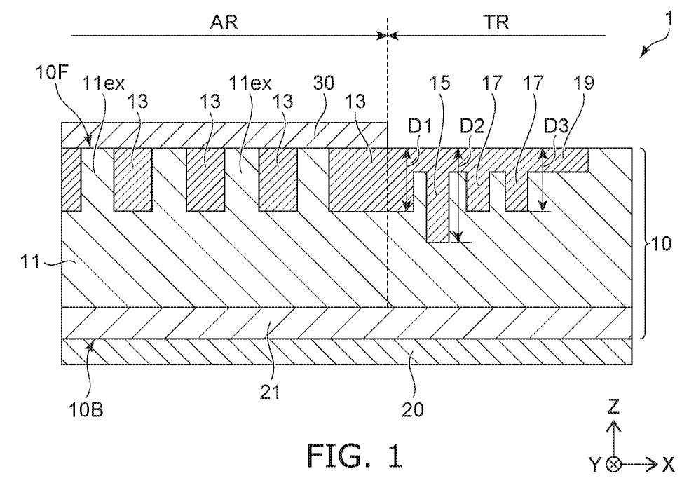

FIG. 1 is a schematic cross-sectional view showing a semiconductor device 1 according to an embodiment. The semiconductor device 1 is, for example, a Schottky barrier diode (SBD). The embodiment is not limited to the SBD; and may be, for example, a MOS transistor and an insulated gate bipolar transistor (IGBT).

As shown in FIG. 1, the semiconductor device 1 includes a semiconductor part 10, a first electrode 20, and a second electrode 30. The semiconductor part 10 is, for example, silicon carbide (SiC). The first electrode 20 is, for example, a cathode electrode. The second electrode 30 is, for example, a Schottky electrode.

The semiconductor part 10 is provided between the first electrode 20 and the second electrodes 30. The first electrode 20 is provided on a back face 10B of the semiconductor part 10. The second electrode 30 is provided on a front surface 10F of the semiconductor part 10. The front surface 10F is on a side opposite to the back face 10B.

The semiconductor part 10 includes, for example, an active region AR and a termination region TR. The active region AR is provided, for example, below the second electrode 30. The termination region TR surrounds the active region AR, for example, in the front surface 10F.

The semiconductor part 10 includes first to sixth semiconductor layers 11, 13, 15, 17, 19 and 21. The first and sixth semiconductor layers 11 and 21 are of a first conductivity type. The second to fifth semiconductor layers 13, 15, 17 and 19 are of a second conductivity type. Hereinafter, the first conductivity type is described as an n-type, and the second conductivity type is described as a p-type.

The first semiconductor layer 11 extends from the active region AR to the termination region TR between the first electrode 20 and the second electrode 30. A plurality of the second semiconductor layers 13 are provided between the first semiconductor layer 11 and the second electrode 30.

The first semiconductor layer 11 includes an extension portion 11ex that extends between the plurality of second semiconductor layers 13. The extension portion 11ex is in contact with the second electrode 30. In the X-direction, the extension portion 11ex is provided between the second semiconductor layers 13. The second electrode 30 is connected to the extension portions 11ex of the first semiconductor layer 11 with, for example, a Schottky junction. The second electrode 30 is connected to the second semiconductor layers 13 at the surface 10F side of the semiconductor part 10. The second electrode 30 is connected to the second semiconductor layers 13 with, for example, an Ohmic junction. The second semiconductor layer 13 may include a p-type impurity with a high concentration enough to provide the Ohmic junction between the second semiconductor layer 13 and the second electrode 30. Alternatively, a silicide contact layer (not shown) may be provided between the second semiconductor layer 13 and the second electrode 30.

The semiconductor part 10 has a so-called RESURF (Reduced Surface Field) structure provided in the termination region TR. The RESURF structure according to the embodiment includes a guard ring (i.e., a guard ringing assisted RESURF). That is, the semiconductor part 10 includes the RESURF structure that is provided in the termination region TR and includes the third semiconductor layer 15, the fourth semiconductor layer 17, and the fifth semiconductor layer 19. The third semiconductor layer 15 and the fourth semiconductor layer 17 serves as guard rings, and are connected to the fifth semiconductor layer 19 which is provided as a main portion of the RESURF structure. Moreover, an insulating film (not shown) such as a silicon oxide film that covers the termination region TR is preferably provided on the fifth semiconductor layer 19.

The third semiconductor layer 15 and the fourth semiconductor layer 17 are provided at the front surface 10F side of the semiconductor part 10. The third semiconductor layer 15 and the fourth semiconductor layer 17 are arranged in a direction along the surface 10F, for example, in the X-direction. The third semiconductor layer 15 is provided between the second semiconductor layer 13 and the fourth semiconductor layer 17. The first semiconductor layer 11 includes a portion extending between the second semiconductor layer 13 and the third semiconductor layer 15 and another portion extending between the third semiconductor layer 15 and the fourth semiconductor layer 17.

At least one fourth semiconductor layer 17 is provided in the termination region TR. In the example, two fourth semiconductor layers 17 are provided in the termination region TR and arranged in the X-direction. One of the two fourth semiconductor layers 17 is provided between the third semiconductor layer 15 and the other of the two fourth semiconductor layers 17. The first semiconductor layer 11 includes other portion extending between the two fourth semiconductor layers 17.

The fifth semiconductor layer 19 is provided above the first semiconductor layer 11 and lies over the second semiconductor layers 13, the third semiconductor layer 15 and the fourth semiconductor layers 17. The fifth semiconductor layer 19 extends over the first semiconductor layer 11, the third semiconductor layer 15 and the fourth semiconductor layers 17 along the front surface 10F of the semiconductor part 10. That is, in the Z-direction, the third semiconductor layer 15 and the fourth semiconductor layer 17 are provided between the first semiconductor layer 11 and the fifth semiconductor layer 19. The first semiconductor layer 11 includes the portion in contact with the fifth semiconductor layer 19 between the third semiconductor layer 15 and the fourth semiconductor layer 17. The first semiconductor layer 11 includes the other portion in contact with the fifth semiconductor layer 19 between the two fourth semiconductor layers 17.

The sixth semiconductor layer 21 is provided between the first semiconductor layer 11 and the first electrode 20. The sixth semiconductor layer 21 includes a first-conductivity-type impurity with a concentration higher than a concentration of a first-conductivity-type impurity in the first semiconductor layer 11. The first electrode 20 is connected to the sixth semiconductor layer 21 with, for example, an Ohmic junction.

As shown in FIG. 1, a first distance D1 in the Z-direction is defined as a distance from the front surface 10F of the semiconductor part 10 to a bottom of the second semiconductor layer 13 (i.e., the distance from the front surface to a boundary in the Z-direction between the first semiconductor layer 11 and the second semiconductor layer 13). A second distance D2 in the Z-direction is defined as another distance from the front surface 10F of the semiconductor part 10 to a lower end of the third semiconductor layer 15 (i.e., the distance from the front surface 10F to a boundary in the Z-direction between the first semiconductor layer 11 and the third semiconductor layer 15). A third distance D3 in the Z-direction is defined as other distance from the front surface 10F of the semiconductor part 10 to a lower end of the fourth semiconductor layer 17 (i.e., the distance from the front surface 10F to a boundary in the Z-direction between the first semiconductor layer 11 and the fourth semiconductor layer 17).

In the semiconductor device 1, when a forward voltage is applied between the first electrode 20 and the second electrode 30, first, a forward current starts to flow through the Schottky junction between the second electrode 30 and the first semiconductor layer 11, and when the forward voltage exceeds a built-in potential between the first semiconductor layer 11 and the second semiconductor layer 13, the forward current mainly flows from the second electrode 30 to the first semiconductor layer 11 through the second semiconductor layer 13. The forward voltage can be reduced thereby.

On the other hand, when a reverse voltage is applied between the first electrode 20 and the second electrode 30, carriers (i.e., electrons and holes) in the first semiconductor layer 11 are ejected to the first electrode 20 and the third electrode 30, and the first semiconductor layer 11 is depleted. Accordingly, an electric field is enlarged in the first semiconductor layer 11. At this time, electric field concentration is remarkably induced at a boundary between the active region AR and the termination region TR, and avalanche breakdown occurs. The RESURF structure is provided to prevent the electric field concentration at the boundary between the active region AR and the termination region TR.

In the RESURF structure according to the embodiment, the third semiconductor layer 15 is provided with the second distance D2 longer than the first distance D1 and the third distance D3. Thereby, it is possible to improve the breakdown voltage of the termination region TR by relaxing the electric field concentration at the lower end of the second semiconductor layer 13 positioned at the termination region TR side.

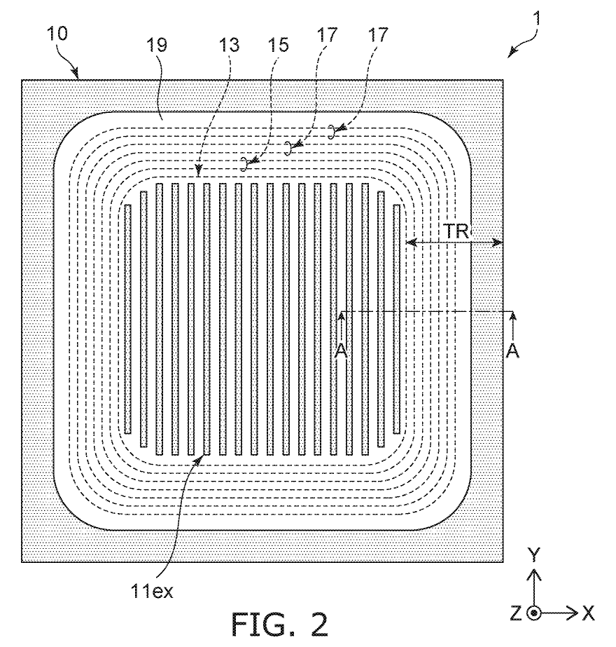

FIG. 2 is a schematic plan view showing the semiconductor device 1 according to the embodiment. FIG. 2 is a plan view showing the front surface 10F of the semiconductor part 10. It should be noted that FIG. 1 is a cross-sectional view along A-A line shown in FIG. 2. Moreover, broken lines in FIG. 2 represent the second semiconductor layer 13, the third semiconductor layer 15, and the fourth semiconductor layer 17, respectively.

As shown in FIG. 2, the third semiconductor layer 15 is provided to surround, for example, the extension portions 11ex of the first semiconductor layer 11 and the second semiconductor layer 13. The fourth semiconductor layer 17 surrounds the termination region TR side of the third semiconductor layer 15. The fifth semiconductor layer 19 surrounds the second semiconductor layer 13. The fifth semiconductor layer 19 extends from the second semiconductor layer 13 into the termination region TR. Moreover, the embodiment is not limited to the example. The third semiconductor layer 15 and the fourth semiconductor layer 17 may include, for example, multiple portions that are apart from each other and surround the second semiconductor layer 13.

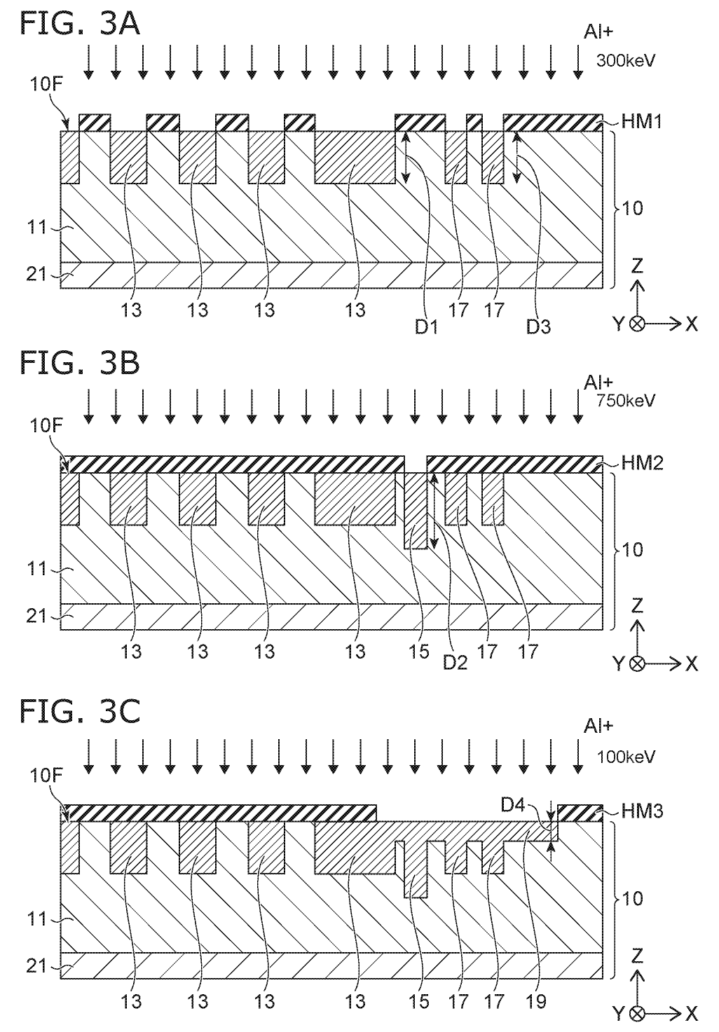

FIGS. 3A-3C are schematic cross-sectional views showing manufacturing processes of the semiconductor device 1 according to the embodiment. FIGS. 3A-3C illustrate the processes for forming the second semiconductor layers 13, the third semiconductor layer 15, the fourth semiconductor layers 17, and the fifth semiconductor layer 19. Here, the first distance D1 is referred as a layer thickness D1; the second distance D2 is referred as a layer thickness D2; and the third distance D3 is referred as a layer thickness D3.

As shown in FIG. 3A, an ion implantation mask HM1 is formed on the front surface 10F of the semiconductor part 10. The ion implantation mask HM1 has first openings provided at an area in the front surface 10F, in which the second semiconductor layers 13 is formed, and provided at another area in the front surface 10F, in which the fourth semiconductor layers 17 are formed.

Subsequently, a second-conductivity-type impurity such as aluminum (Al) is ion-implanted through the first openings of the ion implantation mask HM1. The second-conductivity-type impurity is introduced into the first semiconductor layer 11 with an implantation energy of, for example, 300 keV. The second-conductivity-type impurity ion-implanted into the first semiconductor layer 11 is activated by, for example, heat treatment. The second semiconductor layers 13 and the fourth semiconductor layers 17 are formed thereby. Then, the layer thickness D1 in the Z-direction of the second semiconductor layers 13 is the same as the layer thickness D3 in the Z-direction of the fourth semiconductor layers 17.

As shown in FIG. 3B, after the ion implantation mask HM1 is removed, another ion implantation mask HM2 is formed on the front surface 10F of the semiconductor part 10. The ion implantation mask HM2 has a second opening provided at an area in the front surface 10F of the semiconductor part 10, in which the third semiconductor layer 15 is formed.

Subsequently, the second-conductivity-type impurity such as aluminum (Al) is ion-implanted through the second opening of the ion implantation mask HM2. The second-conductivity-type impurity is introduced into the first semiconductor layer 11 with an implantation energy of, for example, 750 keV.

The second-conductivity-type impurity ion-implanted into the first semiconductor layer 11 is activated by, for example, a heat treatment. Thereby, the third semiconductor layer 15 is formed in the first semiconductor layer 11. The layer thickness D2 in the Z-direction of the third semiconductor layer 15 is thicker than the layer thickness D1 in the Z-direction of the second semiconductor layers 13 and the layer thickness D3 in the Z-direction of the fourth semiconductor layers 17.

As shown in FIG. 3C, after the ion implantation mask HM2 is removed, yet another ion implantation mask HM3 is formed on the surface 10F of the semiconductor part 10. The ion implantation mask HM3 has a third opening at an area in the front surface 10F of the semiconductor part 10, in which the fifth semiconductor layer 19 is formed.

Subsequently, the second-conductivity-type impurity such as aluminum (Al) is ion-implanted through the third opening of the ion implantation mask HM3. The second-conductivity-type impurity is introduced into the first semiconductor layer 11 with an implantation energy of, for example, 100 keV. The second-conductivity-type impurity ion-implanted into the first semiconductor layer 11 is activated by, for example, a heat treatment. The fifth semiconductor layer 19 is formed thereby. The layer thickness D4 in the Z-direction of the fifth semiconductor layer 19 is thinner than the layer thickness D1 in the Z-direction of the second semiconductor layers 13, the layer thickness D2 in the Z-direction of the third semiconductor layer 15, and the layer thickness D3 in the Z-direction of the fourth semiconductor layers 17.

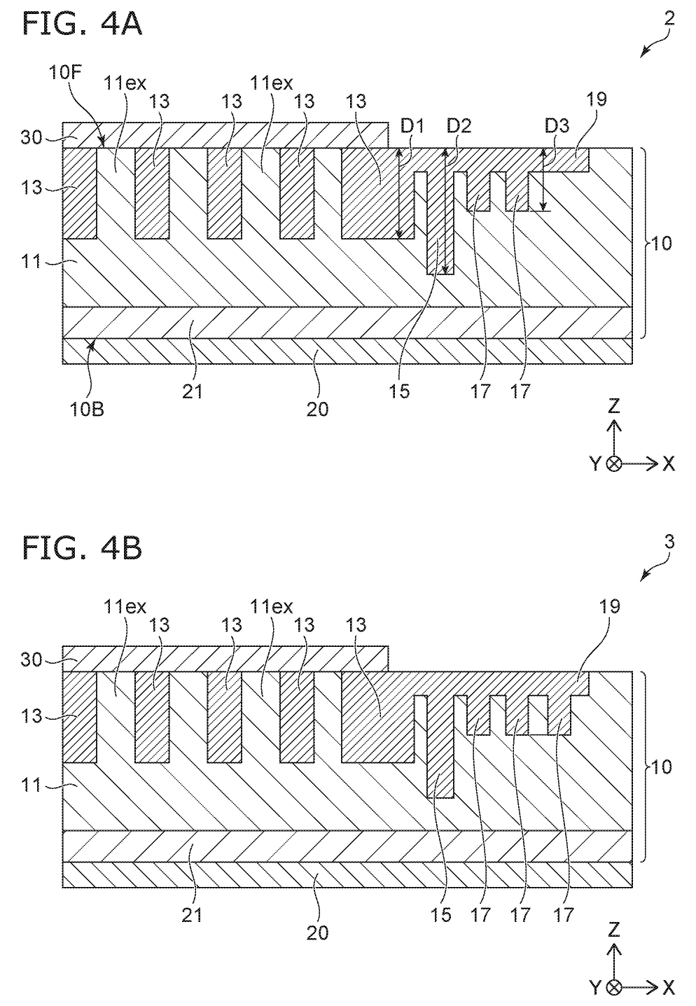

FIGS. 4A and 4B are schematic cross-sectional views showing semiconductor devices 2 and 3 according to variations of the embodiment. FIGS. 4A and 4B are cross-sectional views along A-A line shown in FIG. 2.

As shown in FIG. 4A, the third distance D3 from the front surface 10F of the semiconductor part 10 to the lower end of the fourth semiconductor layer 17 may be shorter than the first distance D1 from the front surface 10F to the lower end of the second semiconductor layer 13. Such a structure can be achieved by forming the fourth semiconductor layer 17 through another ion implantation process different from the ion implantation process of the second semiconductor layer 13.

As shown in FIG. 4B, three fourth semiconductor layers 17 arranged in in the X-direction may be provided. Moreover, any number of the fourth semiconductor layers 17, for example, four or more semiconductor layers 17 may be provided.

The first distance D1 has, for example, an optimum thickness in the active region AR of the second semiconductor layer 13. That is, the second distance D2 is longer than the first distance D1 having the optimum value. The third distance D3 may be at least shorter than the second distance D2. As shown in the example, the third distance D3 also is shorter than the first distance D1. The third distance D3 may be longer than the first distance D1 when the electric field concentration is relaxed at the lower end of the second semiconductor layer 13 on the termination region TR side.

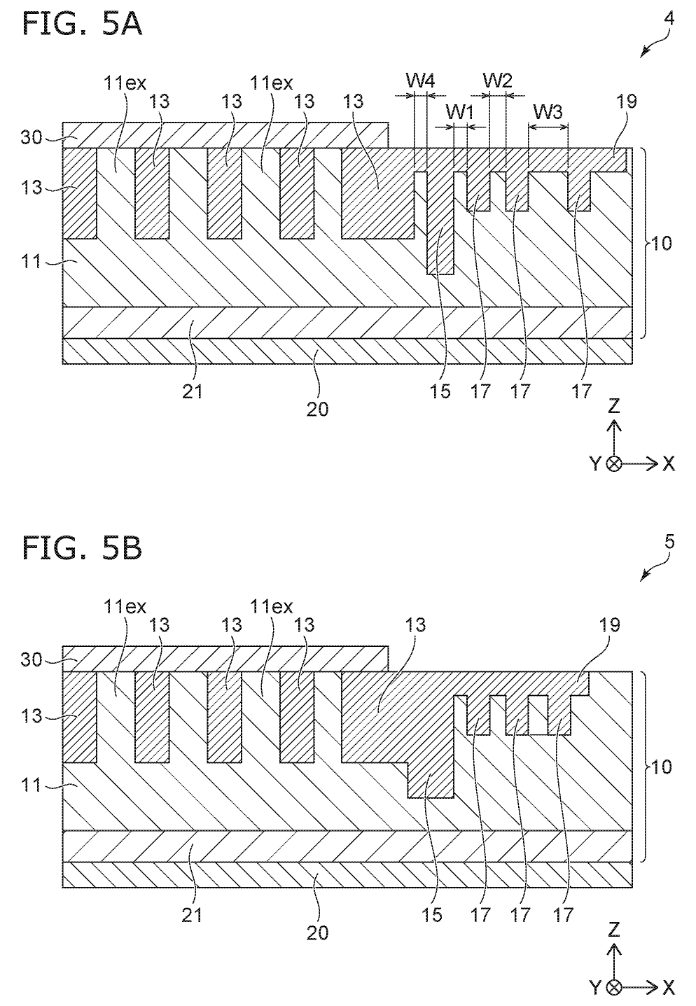

FIG. 5A and 5B are schematic cross-sectional views showing semiconductor devices 4 and 5 according to other variations of the embodiment. FIG. 5A and 5B are cross-sectional views along A-A line shown in FIG. 2.

As shown in FIG. 5A, three fourth semiconductor layers 17 are provided in the example. The three fourth semiconductor layers 17 include first to third fourth semiconductor layers 17. The first fourth semiconductor layer 17 is adjacent to the third semiconductor layer 15. The second fourth semiconductor layer 17 is provided between the first fourth semiconductor layer 17 and the third fourth semiconductor layer 17.

A first width W1 between the third semiconductor layer 15 and the first fourth semiconductor layer 17 is narrower than a second width W2 between the first fourth semiconductor layer 17 and the second fourth semiconductor layer 17. The first width W1 also is narrower than a third width W3 between the second fourth semiconductor layer 17 and the third fourth semiconductor layer 17. Moreover, the second width W2 is narrower than the third width W3. In other words, the widths W2 and W3 between the two adjacent fourth semiconductor layers 17 is narrower as the two adjacent fourth semiconductor layers 17 are apart from the third semiconductor layer 15.

That is, when multiple fourth semiconductor layers 17 arranged in a direction from the active region AR toward the termination region TR, for example, in the X-direction, are provided, the multiple fourth semiconductor layers 17 may have the width between the two adjacent fourth semiconductor layers 17 that is wider as the distance from the third semiconductor layer 15 to the two adjacent fourth semiconductor layer 17 increases. Thereby, a spatial average of the second-conductivity-type impurity concentration decreases in the termination region TR as the distance from the active region AR to the outermost fourth semiconductor layer 14 increases; and it is possible to provide the fourth semiconductor layers 17 with even electric fields. Therefore, the breakdown voltage can be improved at an outer edge of the termination region TR.

Further, a fourth width W4 between the second semiconductor layer 13 and the third semiconductor layer 15 may be the same as the first width W1 or may be different from the first width W1. Moreover, the embodiment is not limited to the example described above. The first width W1 to the fourth width W4 may be provided with any value. The multiple fourth semiconductor layers 17 may be provided with, for example, an evenly spaced arrangement such that the first interval W1, the second interval W2, and the third interval W3 are equal.

As shown in FIG. 5B, the first semiconductor layer 11 may be provided without the portion provided between the second semiconductor layer 13 and the third semiconductor layer 15. The third semiconductor layer 15 may be directly connected to the second semiconductor layer 13. The fourth width W4 disappears and is unnecessary to be controlled. Thereby, the manufacturing process is easier, and the termination region TR may have a narrower width.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor layer of a first conductivity type, the first semiconductor layer including an active region and a termination region, the termination region surrounding the active region;
a first electrode electrically connected to the first semiconductor layer;
a second electrode electrically connected to the first semiconductor layer, the first semiconductor layer being provided between the first and second electrodes, the second electrode being provided on the active region;
a second semiconductor layer of a second conductivity type, the second semiconductor layer being provided between the first semiconductor layer and the second electrode, the second semiconductor layer having a first layer thickness in a first direction directed from the first electrode toward the second electrode;
a third semiconductor layer of the second conductivity type, the third semiconductor layer being provided in the termination region and surrounding the second semiconductor layer, the third semiconductor layer having a second layer thickness in the first direction greater than the first layer thickness;
a fourth semiconductor layer of the second conductivity type, the fourth semiconductor layer being provided in the termination region and surrounding the second and third semiconductor layers, the fourth semiconductor layer being spaced apart from the third semiconductor layer and having a third layer thickness in the first direction less than the second layer thickness; and
a fifth semiconductor layer of the second conductivity type, the fifth semiconductor layer being connected to the second, third, and fourth semiconductor layers, the third and fourth semiconductor layers both being provided between the first and fifth semiconductor layers,
the fourth semiconductor layer including a first part, a second part, and a third part,
the first part being located between the third semiconductor layer and the third part in a second direction directed from the active region toward the termination region, the second direction being orthogonal to the first direction,
the second part being located between the first part and the third part in the second direction,
a first distance in the second direction between the third semiconductor layer and the first part being smaller than a third distance in the second direction between the second and third parts.

2. The semiconductor device according to claim 1, wherein a second distance in the second direction between the first and second parts is smaller than the third distance.

3. The semiconductor device according to claim 2, wherein the second distance is the same as the first distance.

4. The semiconductor device according to claim 1, wherein the second electrode is electrically connected to the second semiconductor layer.

5. The semiconductor device according to claim 4, wherein the second electrode is connected to the first semiconductor layer with a Schottky junction, and is connected to the second semiconductor layer with an Ohmic junction.

6. The semiconductor device according to claim 1, wherein a portion of the first semiconductor layer is in contact with the fifth semiconductor layer.

7. The semiconductor device according to claim 1, wherein the second semiconductor layer is electrically connected via the fifth semiconductor layer to the third and fourth semiconductor layers.
